(19) United States
(12) Patent Application Publication
(10) Pub. No.: US 2026/0026107 A1
(43) Pub. Date: Jan. 22, 2026

(54) ELECTROSTATIC DISCHARGE PROTECTION APPARATUS

(71) Applicant: MACRONIX INTERNATIONAL CO., LTD., Hsinchu (TW)

(72) Inventors: Shih-Yu WANG, Taipei City (TW); Wen-Tsung HUANG, Changhua County (TW); Chih-Wei HSU, Changhua County (TW)

(21) Appl. No.: 18/774,973

(22) Filed: Jul. 17, 2024

(51) Int. Cl. H01L 27/02

(52) U.S. Cl. CPC H10D 89/713

(57) ABSTRACT

An electrostatic discharge protection apparatus includes a substrate, a first well disposed in the substrate and having a first conductivity type, a second well disposed in the first well and having a second conductivity type different from the first conductivity type, a first doping region disposed in the substrate and separated from the second well and having the second conductivity type, a second doping region disposed in the second well and having the first conductivity type, a first terminal and a second terminal electrically connected to the first and second doping regions, respectively. The substrate, the first well, the second well, the first doping region and the second doping region form a first silicon controlled rectifier. Electrostatic discharge current flowing from the first terminal into the first doping region flows to the second doping region through the first silicon controlled rectifier, and enters the second terminal.

### BACKGROUND OF THE INVENTION

### Field of the Invention

The invention relates in general to a semiconductor apparatus, and more particularly to an electrostatic discharge protection apparatus.

### Description of the Related Art

Electrostatic discharge is a charge transfer phenomenon caused by the proximity of two objects with different potentials. In the design of semiconductor apparatuses, due to human body discharge or machine discharge, the current caused by electrostatic discharge can easily cause damage to the inside of the circuit. Therefore, how to design an effective electrostatic discharge protection apparatus in a semiconductor apparatus has become a very important issue.

### SUMMARY OF THE INVENTION

The invention is directed to an electrostatic discharge protection apparatus, which can effectively prevent electrostatic discharge from causing damage to the inside of the circuit.

According to an embodiment of an electrostatic discharge protection apparatus is provided. The electrostatic discharge protection apparatus includes a substrate, a first well disposed in the substrate and having a first conductivity type, a second well disposed in the first well and having a second conductivity type, a first doping region disposed in the substrate and separated from the second well and having the second conductivity type, a second doping region disposed in the second well and having the first conductivity type, a first terminal electrically connected to the first doping region and a second terminal electrically connected to the second doping region. The first conductivity type is different from the second conductivity type. The substrate, the first well, the second well, the first doping region and the second doping region form a first silicon controlled rectifier. Electrostatic discharge current flowing from the first terminal into the first doping region flows to the second doping region through the first silicon controlled rectifier, and enters the second terminal.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A is a schematic diagram of an electrostatic discharge protection apparatus according to a first embodiment of the present invention.

FIG. 1B shows an equivalent capacitance diagram of the electrostatic discharge protection apparatus in FIG. 1A.

FIG. 1C shows a partial cross-sectional view of the electrostatic discharge protection apparatus in FIG. 1A.

FIG. 1D shows a current-voltage diagram between a conductive pad and a first conductive terminal of the electrostatic discharge protection apparatus in FIG. 1C.

FIG. 2A shows a schematic diagram of an electrostatic discharge protection apparatus according to a comparative example.

FIG. 2B shows an equivalent capacitance diagram of the electrostatic discharge protection apparatus in FIG. 2A.

FIG. 2C shows a partial cross-sectional view of the electrostatic discharge protection apparatus in FIG. 2A.

FIG. 3A shows the capacitance-voltage diagram of the areas between the conductive pads and the first conductive terminals of the electrostatic discharge protection apparatuses of Embodiments A and B and Comparative Example A.

FIG. 3B shows the capacitance-voltage diagram of the areas between the second conductive terminals and the conductive pads of the electrostatic discharge protection apparatuses of Embodiments A and B and Comparative Example A.

FIG. 4 shows a partial cross-sectional view of an electrostatic discharge protection apparatus according to a second embodiment of the present invention.

FIG. 5 shows a partial cross-sectional view of an electrostatic discharge protection apparatus according to a third embodiment of the present invention.

FIG. 6 shows a partial cross-sectional view of an electrostatic discharge protection apparatus according to a fourth embodiment of the present invention.

FIG. 7 shows a partial cross-sectional view of an electrostatic discharge protection apparatus according to a fifth embodiment of the present invention.

FIG. 8 shows a partial cross-sectional view of an electrostatic discharge protection apparatus according to a sixth embodiment of the present invention.

### DETAILED DESCRIPTION OF THE INVENTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. The details of the structures of the embodiments can be changed and modified according to the needs of the actual application process without departing from the spirit and scope of the present invention. The following description uses the same/similar symbols to indicate the same/similar components. It is contemplated that the elements and features of one embodiment can be beneficially incorporated in another embodiment without further recitation.

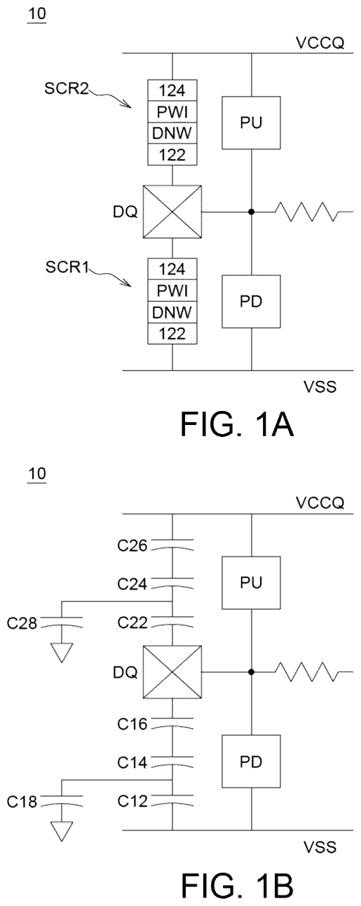

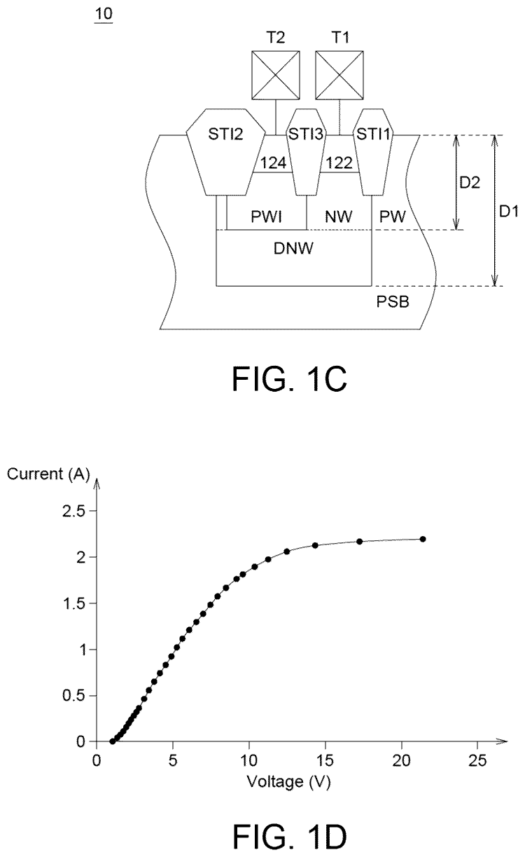

FIG. 1A is a schematic diagram of an electrostatic discharge protection apparatus 10 according to a first embodiment of the present invention. FIG. 1B shows an equivalent capacitance diagram of the electrostatic discharge protection apparatus 10 in FIG. 1A. FIG. 1C shows a partial cross-sectional view of the electrostatic discharge protection apparatus 10 in FIG. 1A. FIG. 1D shows a current-voltage (I-V) diagram between a conductive pad DQ and a first conductive terminal VCCQ of the electrostatic discharge protection apparatus 10 in FIG. 1C.

Referring to FIG. 1A, the electrostatic discharge protection apparatus 10 comprises a first conductive terminal VCCQ, a conductive pad DQ, a second conductive terminal VSS and silicon controlled rectifiers SCR1 and SCR2. The silicon controlled rectifier SCR1 is electrically connected between the conductive pad DQ and the second conductive terminal VSS. The silicon controlled rectifier SCR2 is electrically connected between the first conductive terminal VCCQ and the conductive pad DQ. The structure of the silicon controlled rectifier SCR1 may be the same as the structure of the silicon controlled rectifier SCR2. That is, the silicon controlled rectifiers SCR1 and SCR2 comprise a first well DNW, a second well PWI, a first doping region 122 and a second region 124, respectively (detailed below), but the present invention is not limited thereto. Electrostatic discharge current may flow from the second conductive terminal VSS into the first doping region 122 of the first silicon controlled rectifier SCR1, and may sequentially flow through the first well DNW, the second well PWI and the second doping region 124 (i.e. flows through the first silicon controlled rectifier SCR1), and may enter the conductive pad DQ. Besides, the electrostatic discharge current may flow from the conductive pad DQ into the first doping region 122 of the second silicon controlled rectifier SCR2, and may sequentially flow through the first well DNW, the second well PWI and the second doping region 124 (i.e. flows through the second silicon controlled rectifier SCR2), and may enter the first conductive terminal VCCQ. In some embodiments, the potential of the first conductive terminal VCC may be higher than the potential of the second conductive terminal VSS, and the second conductive terminal VSSQ is the ground terminal. In the present embodiment, the first conductive terminal VCCQ, the conductive pad DQ and the second conductive terminal VSS are electrically connected to a first transistor PU and a second transistor PD, but the invention is not limited thereto.

Referring to FIGS. 1A and 1C at the same time, FIG. 1C illustrates a partial structure corresponding to a current path between the conductive pad DQ and the second conductive terminal VSS (corresponding to the second silicon controlled rectifier SCR2), or FIG. 1C illustrates a partial structure corresponding to a current path between the first conductive terminal VCCQ and the conductive pad DQ (corresponding to the first silicon controlled rectifier SCR1). That is, when the first terminal T1 of FIG. 1C is the conductive pad DQ of FIG. 1A, the second terminal T2 of FIG. 1C is the first conductive terminal VCCQ of FIG. 1A; when the first terminal T1 of FIG. 1C is the second conductive terminal VSS of FIG. 1A, the second terminal T2 of FIG. 1C is the conductive pad DQ of FIG. 1A.

As shown in FIG. 1C, the electrostatic discharge protection apparatus 10 comprises a substrate PSB, a first well DNW, a second well PWI, a first doping region 122, a second doping region 124, a first terminal T1 and a second terminal T2. The first well DNW is disposed in the substrate PSB, and the first well DNW has a first conductivity type. The second well PWI is disposed in the first well DNW, and the second well PWI has a second conductivity type. The first doing region 122 is disposed in the substrate PSB and is separated from the second well PWI, and the first doping region 122 has the second conductivity type. The second doping region 124 is disposed in the second well PWI and the second doping region 124 has the first conductivity type. The first terminal T1 is electrically connected to the first doing region 122. The second terminal T2 is electrically connected to the second doping region 124. The first conductivity type is different from the second conductivity type. For example, the first conductivity type is N type and the second conductivity type is P type. The substrate PSB is, for example, a p-type substrate. The substrate PSB, the first well DNW, the second well PWI, the first doping region 122 and the second doping region 124 form the silicon controlled rectifier SCR1 or SCR2. The electrostatic discharge current flowing from the first terminal T1 into the first doping region 122 sequentially flows through the first well DNW and the second well PWI to the second doping region 124 (i.e. through the first silicon controlled rectifier SCR1 or SCR2), and enters the second terminal T2. The first well DNW and the second well PWI are floating. Moreover, when the first terminal T1 is the second conductive terminal VSS and the second terminal T2 is the conductive pad DQ, the electrostatic discharge protection apparatus 10 further comprises a third terminal T3, and the third terminal T3 is the first conductive terminal VCCQ. The electrostatic discharge current may enter the silicon controlled rectifier SCR1 from the first terminal T1 (i.e. second conductive terminal VSS) and flow to the second terminal T2 (i.e. conductive pad DQ), and may also enter the silicon controlled rectifier SCR2 from the second terminal T2 (i.e. conductive pad DQ) and flow to the third terminal T3 (i.e. first conductive terminal VCCQ).

According to FIG. 1C, the electrostatic discharge protection apparatus 10 further comprises a first shallow well PW, a second shallow well NW, a first isolation structure STI1, a second isolation structure STI2 and a third isolation structure STI3. The first shallow well PW is disposed in the substrate PSB and adjacent to the first well DNW, and has the second conductivity type. The second shallow well NW is disposed in the first well DNW and adjacent to the second well PWI, and has the first conductivity type. The depth D1 of the first well DNW is greater than the depth D2 of the second well PWI. The first shallow well PW, the second shallow well NW and the second well PWI may have the same or similar depth D2. The doping concentration of the second doping region 124 (e.g., the concentration of N-type dopant) is greater than the doping concentration of the first well DNW (e.g., the concentration of N-type dopant), and the doping concentration of the first doping region 122 (e.g., the concentration of the P-type dopant) is greater than the doping concentration of the second well PWI (e.g., the concentration of the P-type dopant). The doping concentration of the first shallow well PW (e.g., the concentration of the P-type dopant) is greater than the doping concentration of the substrate PSB (e.g., the concentration of the P-type dopant). In the present embodiment, the first doping region 122 is disposed in the first well DNW. More specifically, the first doping region 122 is disposed in the second shallow well NW in the first well DNW. However, the present invention is not limited thereto. The first isolation structure STI1 is disposed between the substrate PSB and the first doping region 122 (that is, between the first shallow well PW disposed in the substrate PSB and the first doping region 122). The second isolation structure STI2 is disposed between the second doping region 124 and the substrate PSB. The third isolation structure STI3 is disposed between the first isolation structure STI1 and the second isolation structure STI2, and between the first doping region 122 and the second doping region 124.

As shown in FIGS. 1A-1C, the first well DNW in the silicon controlled rectifier SCR1 or SCR2 has a first conductivity type (for example, N type), the second well PWI has a second conductivity type (for example, P type), the first doping region 122 has a second conductivity type (for example, P type), the second doping region 124 has a first conductivity type (for example, N type), and the first conductivity type (for example, N type) is different from the second conductivity type (for example, P type). The silicon controlled rectifiers SCR1 and SCR2 respectively include three PN interfaces, that is, including the PN interface between the first doping region 122 and the first well DNW, the PN interface between the first well DNW and the second well PWI, and the PN interface between the second well PWI and the second doping region 124, such that three capacitors are connected in series between the first terminal T1 and the second terminal T2. In addition, a parallel capacitor is also formed between the first shallow well PW in the substrate PSB and the first well DNW. As shown in FIG. 1B, in the electrostatic discharge path between the second conductive terminal VSS and the conductive pad DQ, a capacitor C12 is formed between the first doping region 122 and the first well DNW corresponding to the silicon controlled rectifier SCR1; a capacitor C14 is formed between the first well DNW and the second well PWI corresponding to the silicon controlled rectifier SCR1; a capacitor C16 is formed between the second well PWI and the second doping region 124 corresponding to the silicon controlled rectifier SCR1; a capacitor C18 is formed between the first shallow well PW and the first well DNW in the substrate PSB corresponding to the silicon controlled rectifier SCR1. That is, capacitors C12, C14, and C16 are connected in series with each other and in parallel with the capacitor C18, and the capacitor C18 can be connected to ground. In the electrostatic discharge path between the conductive pad DQ and the first conductive terminal VCCQ, a capacitor C22 is formed between the first doping region 122 and the first well DNW corresponding to the silicon controlled rectifier SCR2; a capacitor C24 is formed between the first well DNW and the second well PWI, a capacitor C26 is formed between the second well PWI and the second doping region 124 corresponding to the silicon controlled rectifier SCR2; a capacitor C28 is formed between the first shallow well PW in the substrate PSB and the first well DNW. That is, capacitors C22, C24 and C26 are connected in series with each other and in parallel with capacitor C28, and the capacitor C28 can be connected to ground.

Referring to FIG. 1D, the relationship between the current (A) and the voltage (V) between the conductive pad DQ and the first conductive terminal VCCQ of the electrostatic discharge protection apparatus 10 can be determined by a transmission line pulse (TLP) for evaluation. As shown in the results of FIG. 1D, the current can be generated under a very small voltage, that is, a current path can be formed immediately at a low voltage, so the silicon controlled rectifier SCR1 between the conductive pad DQ and the first conductive terminal VCCQ has characteristics similar to the characteristics of a forward diode. The silicon controlled rectifier SCR2 between the second conductive terminal VSS and the conductive pad DQ also has characteristics similar to the characteristics of a forward diode (not shown).

The structure and characteristics of the electrostatic discharge protection apparatus 10 according to an embodiment of the present invention and the electrostatic discharge protection apparatus 10CB according to a comparative example will be further compared below.

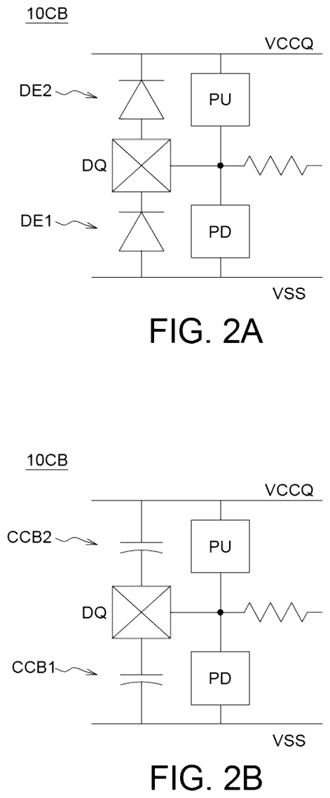

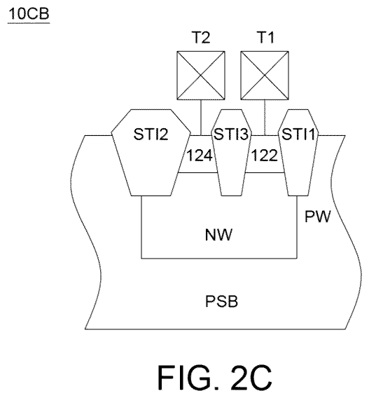

FIG. 2A shows a schematic diagram of an electrostatic discharge protection apparatus 10CB according to a comparative example. FIG. 2B shows an equivalent capacitance diagram of the electrostatic discharge protection apparatus 10CB of FIG. 2A. FIG. 2C shows a partial cross-sectional view of the electrostatic discharge protection apparatus 10CB in FIG. 2A.

Referring to FIGS. 2A-2C at the same time, the difference between the electrostatic discharge protection apparatus 10CB and the electrostatic discharge protection apparatus 10 is that there is a diode DE1 between the second conductive terminal VSS and the conductive pad DQ, and there is a diode DE2 between the conductive pad DQ and the first conductive terminal VCCQ, but there is no silicon controlled rectifiers SCR1 and SCR2. In other words, the electrostatic discharge protection apparatus 10CB is not provided with the second well PWI, and the diode DE1 or DE2 only has a PN interface to form a capacitor CCB1 or CCB2. Other parts of the electrostatic discharge protection apparatus 10CB that are the same or similar to the electrostatic discharge protection apparatus 10 will not be described in detail.

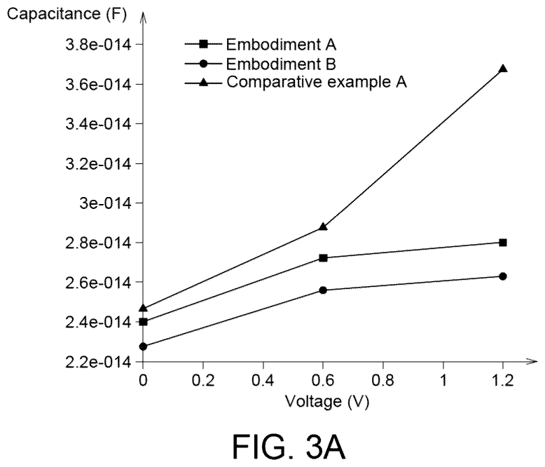

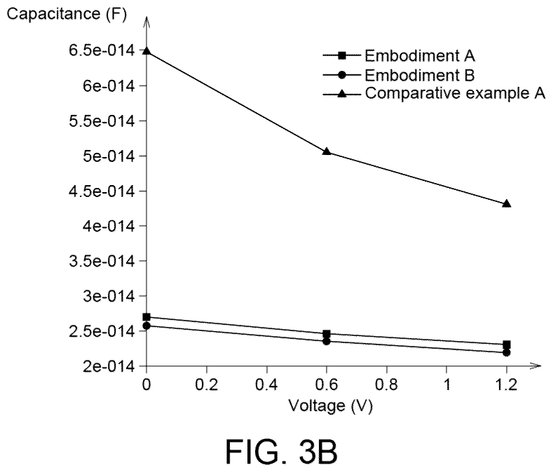

FIG. 3A shows a capacitance (F)-voltage (V) diagram of the area between the conductive pads DQ and the first conductive terminals VCCQ of the electrostatic discharge protection apparatuses of Embodiments A and B and Comparative Example A. FIG. 3B shows the capacitance-voltage diagram of the area between the second conductive terminals VSS and the conductive pads DQ of the electrostatic discharge protection apparatuses of Embodiments A and B and Comparative Example A.

Embodiments A and B are electrostatic discharge protection apparatuses 10 as shown in FIGS. 1A to 1C. The difference between Embodiments A and B is only that the doping concentration is slightly different. Comparative Example A is an electrostatic discharge protection apparatus 10CB as shown in FIGS. 2A to 2C.

As shown in FIGS. 3A to 3B, whether it is the area between the conductive pad DQ and the first conductive terminal VCCQ, or the area between the second conductive terminal VSS and the conductive pad DQ, the capacitance of Embodiment A and the capacitance of Embodiment B are all smaller than the capacitance of Comparative Example A. It can be seen that, compared with the electrostatic discharge protection apparatus 10CB of the comparative example, the electrostatic discharge protection apparatus 10 according to one embodiment of the present invention can effectively reduce the parasitic capacitance.

With the increase in data speed, the size of the diode DE1 or DE2 in the electrostatic discharge protection apparatus 10CB needs to be reduced to produce a lower parasitic capacitance. However, reducing the size of the diode DE1 or DE2 will reduce the capability of electrostatic discharge protection. Compared with the comparative example, the electrostatic discharge protection apparatus according to one embodiment of the present invention includes a silicon controlled rectifier, which can have smaller parasitic capacitance and maintain good capabilities in the electrostatic discharge protection.

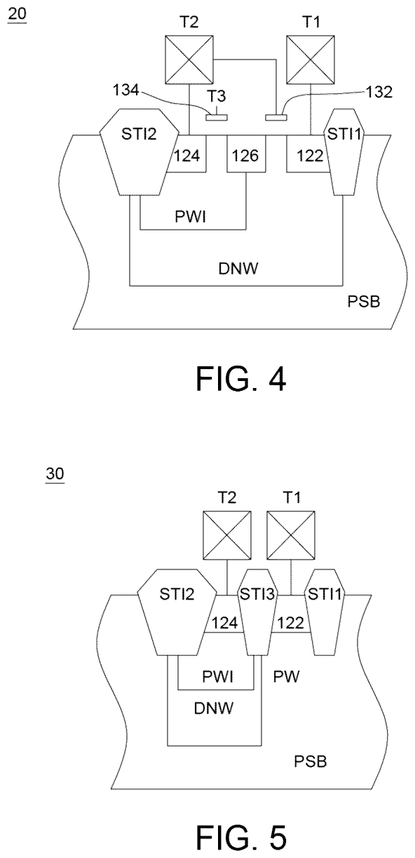

FIG. 4 shows a partial cross-sectional view of the electrostatic discharge protection apparatus 20 according to a second embodiment of the present invention. One of the differences between the electrostatic discharge protection apparatus 20 and the electrostatic discharge protection apparatus 10 is that the third isolation structure STI3 is replaced by a third doping region 126, a first gate structure 132 and a second gate structure 134, and the other identical or similar parts will not be described in detail.

Referring to FIG. 4, the electrostatic discharge protection apparatus 20 comprises a third doping region 126, wherein the third doping region 126 is disposed between the first doping region 122 and the second doping region 124, and is disposed between the first well DNW and the second well PWI. In one embodiment, the third doping region 126 has a first conductivity type (for example, N-type), and the doping concentration of the third doping region 126 (for example, the concentration of N-type dopant) is greater than the doping concentration of the first well region DNW (for example, the concentration of N-type dopant). In another embodiment, the third doping region 126 has a second conductivity type (for example, P-type), and the doping concentration of the third doping region 126 (for example, the concentration of P-type dopant) is greater than the doping concentration of the second well PWI (for example, the concentration of the P-type dopant). The electrostatic discharge protection apparatus 20 further includes a first gate structure 132 and a second gate structure 134. The first gate structure 132 and the second gate structure 134 are disposed on the substrate PSB, wherein the first gate structure 132 is disposed between the first doping region 122 and the third doping region 126, the second gate structure 134 is disposed between the second doping region 124 and the third doping region 126. A gate oxide layer (not shown) may be disposed between the first gate structure 132 and the substrate PSB. A gate oxide layer (not shown) may be disposed between the second gate structure 134 and the substrate PSB. The materials of the first gate structure 132 and the second gate structure 134 may be polysilicon, metal, or other suitable gate materials. In the present embodiment, the first terminal T1 is the conductive pad DQ; the second terminal T2 is the first conductive terminal VCCQ; the third terminal T3 is the second conductive terminal VSS; the first gate structure 132 is electrically connected to the second terminal T2, and the second gate structure 134 is electrically connected to the third terminal T3, but the present invention is not limited thereto. The first gate structure 132 and the second gate structure 134 can be connected to appropriate potentials respectively, as long as the purpose of not generating leakage is achieved. It should be understood that the substrate PSB of FIG. 4 may include a first shallow well PW as shown in FIG. 1C, and the first well DNW of FIG. 4 may include a second shallow well NW as shown in FIG. 1C. The drawing omits the first shallow well PW and the second shallow well NW.

Compared with the electrostatic discharge protection apparatus 10, since the electrostatic discharge protection apparatus 20 does not include the third isolation structure STI3, the gap between the first doping region 122 and the second doping region 124 of the electrostatic discharge protection apparatus 20 can have a shorter current path. Similarly, the electrostatic discharge current flows into the first doping region 122 through the first terminal T1, and sequentially flow through the first well DNW, the second well PWI and the second doping region 124, and then flows to the second terminal T2.

FIG. 5 shows a partial cross-sectional view of an electrostatic discharge protection apparatus 30 according to a third embodiment of the present invention. One of the differences between the electrostatic discharge protection apparatus 30 and the electrostatic discharge protection apparatus 10 is that the range of the first well DNW is different, and other identical or similar parts will not be described in detail.

Referring to FIG. 5, the first well DNW in the electrostatic discharge protection apparatus 30 extends between the second isolation structure STI2 and the third isolation structure STI3, and does not extend to the first isolation structure STI1. The first doping region 122 is disposed in the first shallow well PW rather than in the first well DNW. In the present embodiment, the first terminal T1 is the second conductive terminal VSS, and the second terminal T2 is the conductive pad DQ, but the present invention is not limited thereto. The electrostatic discharge current flows into the first doping region 122 through the first terminal T1, and sequentially flows through the first shallow well PW, the first well DNW, the second well PWI and the second doping region 124, and then flows to the second terminal T2.

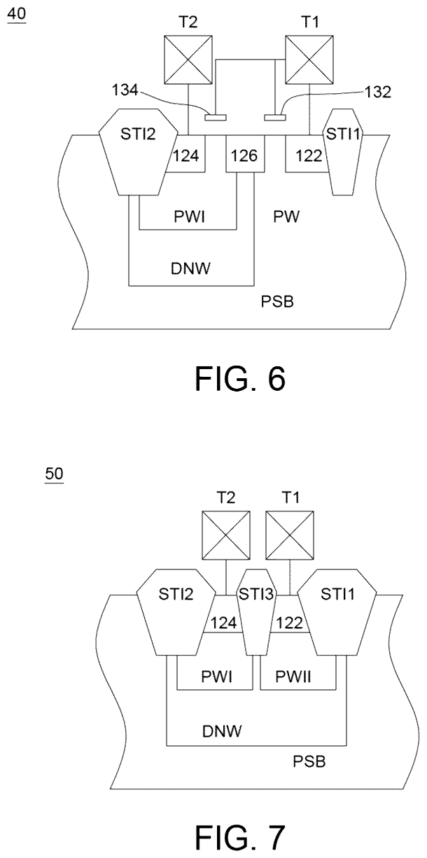

FIG. 6 shows a partial cross-sectional view of an electrostatic discharge protection apparatus 40 according to a fourth embodiment of the present invention. One of the differences between the electrostatic discharge protection apparatus 40 and the electrostatic discharge protection apparatus 30 is that the third isolation structure STI3 is replaced by the third doping region 126, the first gate structure 132 and the second gate structure 134, and the other identical or similar parts will not be described in detail.

Referring to FIG. 6, the electrostatic discharge protection apparatus 40 includes a third doping region 126, wherein the third doping region 126 is disposed between the first doping region 122 and the second doping region 124, and is disposed between the first well DNW, the second well PWI and the first shallow well PW. In one embodiment, the third doping region 126 has a first conductivity type (for example, N-type), and the doping concentration of the third doping region 126 (for example, the concentration of N-type dopant) is greater than the doping concentration of the first well DNW (for example, the concentration of N-type dopant). The electrostatic discharge protection apparatus 40 further includes a first gate structure 132 and a second gate structure 134. The first gate structure 132 and the second gate structure 134 are disposed on the substrate PSB, wherein the first gate structure 132 is disposed between the first doping region 122 and the third doping region 126, and the second gate structure 134 is disposed between the second doping region 124 and the third doping region 126. A gate oxide layer (not shown) may be disposed between the first gate structure 132 and the substrate PSB. A gate oxide layer (not shown) may be disposed between the second gate structure 134 and the substrate PSB. The materials of the first gate structure 132 and the second gate structure 134 may be polysilicon, metal, or other suitable gate materials. In the present embodiment, the first terminal T1 is the second conductive terminal VSS, the second terminal T2 is the conductive pad DQ, and the first gate structure 132 and the second gate structure 134 are electrically connected to the first terminal T1. However, the present invention is not limited thereto. The first gate structure 132 and the second gate structure 134 can be connected to appropriate potentials respectively, as long as the purpose of preventing current leakage is achieved.

Compared with the electrostatic discharge protection apparatus 30, since the electrostatic discharge protection apparatus 40 does not include the third isolation structure STI3, the gap between the first doping region 122 and the second doping region 124 of the electrostatic discharge protection apparatus 40 can have a shorter current path. Similarly, the electrostatic discharge current flows into the first doping region 122 through the first terminal T1, and sequentially flows through the first shallow well PW, the first well DNW, the second well PWI and the second doping region 124, and then flows to the second terminal T2.

FIG. 7 shows a partial cross-sectional view of an electrostatic discharge protection apparatus 50 according to a fifth embodiment of the present invention. One of the differences between the electrostatic discharge protection apparatus 50 and the electrostatic discharge protection apparatus 10 is that the electrostatic discharge protection apparatus 50 further includes a third well PWII, and other identical or similar parts will not be described in detail.

Referring to FIG. 7, the third well PWII is disposed in the first well DNW and is separated from the second well PWI. The third well PWII has a second conductivity type (for example, P type), wherein the first doping region 122 is disposed in the third well PWII. A depth of the third well PWII may be the same as or similar to the depth of the second well PWI. The doping concentration of the third well PWII (for example, the concentration of P-type dopant) may be the same or similar to the doping concentration of the second well PWI (for example, the concentration of P-type dopant). In the present embodiment, the first terminal T1 is the conductive pad DQ, and the second terminal T2 is the second conductive terminal VCCQ. However, the present invention is not limited thereto. The electrostatic discharge current flows into the first doping region 122 through the first terminal T1, and sequentially flows through the third well PWII, the first well DNW, the second well PWI and the second doping region 124, and then flows to the second terminal T2.

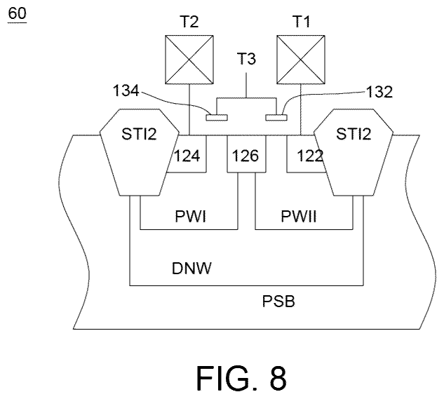

FIG. 8 shows a partial cross-sectional view of an electrostatic discharge protection apparatus 60 according to a sixth embodiment of the present invention. One of the differences between the electrostatic discharge protection apparatus 60 and the electrostatic discharge protection apparatus 50 is that the third isolation structure STI3 is replaced by the third doping region 126, the first gate structure 132 and the second gate structure 134, and the other identical or similar parts will not be described in detail.

Referring to FIG. 8, the electrostatic discharge protection apparatus 60 includes a third doping region 126, wherein the third doped region 126 is disposed between the first doping region 122 and the second doping region 124, and is disposed between the first well DNW, the second well PWI and the third well PWII. In one embodiment, the third doping region 126 has a first conductivity type (for example, N-type), and the doping concentration of the third doping region 126 (for example, the concentration of N-type dopant) is greater than the doping concentration of the first well DNW. The electrostatic discharge protection apparatus 60 further includes a first gate structure 132 and a second gate structure 134. The first gate structure 132 and the second gate structure 134 are disposed on the substrate PSB, wherein the first gate structure 132 is disposed between the first doped region 122 and the third doping region 126, and the second gate structure 134 is disposed between the second doping region 124 and the third doping region 126. A gate oxide layer (not shown) may be disposed between the first gate structure 132 and the substrate PSB. A gate oxide layer (not shown) may be disposed between the second gate structure 134 and the substrate PSB. The materials of the first gate structure 132 and the second gate structure 134 may be polysilicon, metal, or other suitable gate materials. In the present embodiment, the first terminal T1 is the conductive pad DQ, the second terminal T2 is the first conductive terminal VCCQ, the third terminal T3 is the second conductive terminal VSS, the first gate structure 132 and the second gate structure 134 are electrically connected to the third terminal T3, but the present invention is not limited thereto. The first gate structure 132 and the second gate structure 134 can be connected to appropriate potentials respectively, as long as the purpose of not generating leakage is achieved. It should be understood that the substrate PSB in FIG. 8 may include the first shallow well PW as shown in FIG. 1C, the first well DNW in FIG. 8 may include the second shallow well NW as shown in FIG. 1C, and the first shallow well PW and the second shallow well NW are omitted in FIG. 8.

Compared with the electrostatic discharge protection apparatus 50, since the electrostatic discharge protection apparatus 60 does not include the third isolation structure STI3, the gap between the first doping region 122 and the second doping region 124 of the electrostatic discharge protection apparatus 60 can have a shorter current path. Similarly, the electrostatic discharge current flows into the first doping region 122 through the first terminal T1, and sequentially flows through the third well PWII, the first well DNW, the second well PWI and the second doping region 124, and then flows to the second terminal T2.

According to the contents described above, an electrostatic discharge protection apparatus is provided in an embodiment of the present invention. The electrostatic discharge protection apparatus includes a substrate, a first well disposed in the substrate and having a first conductivity type, a second well disposed in the first well and having a second conductivity type, a first doping region disposed in the substrate and separated from the second well and having the second conductivity type, a second doping region disposed in the second well and having the first conductivity type, a first terminal electrically connected to the first doping region and a second terminal electrically connected to the second doping region. The first conductivity type is different from the second conductivity type. The substrate, the first well, the second well, the first doping region and the second doping region form a first silicon controlled rectifier. Electrostatic discharge current flowing from the first terminal into the first doping region flows to the second doping region through the first silicon controlled rectifier, and enters the second terminal. Compared with the comparative example that includes a diode but does not include a silicon controlled rectifier, the electrostatic discharge protection apparatus of the present invention includes a silicon controlled rectifier and can have smaller parasitic capacitance, so it can have better electrostatic discharge protection capabilities.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electrostatic discharge protection apparatus, comprising:
a substrate;
a first well disposed in the substrate and having a first conductivity type;
a second well disposed in the first well and having a second conductivity type;
a first doping region disposed in the substrate and separated from the second well and having the second conductivity type;
a second doping region disposed in the second well and having the first conductivity type;
a first terminal electrically connected to the first doping region; and
a second terminal electrically connected to the second doping region,
wherein the first conductivity type is different from the second conductivity type; the substrate, the first well, the second well, the first doping region and the second doping region form a first silicon controlled rectifier; electrostatic discharge current flowing from the first terminal into the first doping region flows to the second doping region through the first silicon controlled rectifier, and enters the second terminal.

2. The electrostatic discharge protection apparatus according to claim 1, wherein the first well and the second well are floating.

3. The electrostatic discharge protection apparatus according to claim 1, wherein the first doping region is disposed in the first well.

4. The electrostatic discharge protection apparatus according to claim 1, further comprising a first isolation structure and a second isolation structure, wherein the first isolation structure is disposed between the substrate and the first doping region, and the second isolation structure is disposed between the second doping region and the substrate.

5. The electrostatic discharge protection apparatus according to claim 4, further comprising a third isolation structure, wherein the third isolation structure is disposed between the first isolation structure and the second isolation structure, and disposed between the first doping region and the second doping region.

6. The electrostatic discharge protection apparatus according to claim 1, further comprising a third doping region, wherein the third doping region is disposed between the first doping region and the second doping region, and is disposed between the first well and the second well.

7. The electrostatic discharge protection apparatus according to claim 6, wherein the third doping region has the first conductivity type.

8. The electrostatic discharge protection apparatus according to claim 6, wherein the third doping region has the second conductivity type.

9. The electrostatic discharge protection apparatus according to claim 6, further comprising a first gate structure and a second gate structure, the first gate structure and the second gate structure disposed on the substrate, wherein the first gate structure is disposed between the first doping region and the third doping region, and the second gate structure is disposed between the second doping region and the third doping region.

10. The electrostatic discharge protection apparatus according to claim 6, further comprising a first shallow well disposed in the substrate and adjacent to the first well, the first shallow well having the second conductivity type, wherein the first doping region is disposed in the first shallow well, and the third doping region is disposed between the first well, the second well and the first shallow well.

11. The electrostatic discharge protection apparatus according to claim 6, further comprising a third well disposed in the first well and separated from the second well, the third well having the second conductivity type, wherein the first doping region is disposed in the third well, and the third doping region is disposed between the first well, the second well and the third well.

12. The electrostatic discharge protection apparatus according to claim 1, further comprising a first shallow well disposed in the substrate and adjacent to the first well, the first shallow well having the second conductivity type, wherein the first doping region is disposed in the first shallow well.

13. The electrostatic discharge protection apparatus according to claim 1, further comprising a third well disposed in the first well and separated from the second well, the third well having the second conductivity type, wherein the first doping region is disposed in the third well.

14. The electrostatic discharge protection apparatus according to claim 1, further comprising a third terminal, the electrostatic discharge current flowing from the second terminal into a second silicon controlled rectifier and flowing to the third terminal, wherein a structure of the second silicon controlled rectifier is the same as a structure of the first silicon controlled rectifier.

15. The electrostatic discharge protection apparatus according to claim 1, wherein a depth of the first well is greater than a depth of the second well.

16. The electrostatic discharge protection apparatus according to claim 1, wherein a doping concentration of the second doping region is greater than a doping concentration of the first well, and a doping concentration of the first doping region is greater than a doping concentration of the second well.

17. The electrostatic discharge protection apparatus according to claim 1, wherein the first conductivity type is N type, and the second conductivity type is P type.

18. The electrostatic discharge protection apparatus according to claim 1, wherein the first silicon controlled rectifier comprises three PN interfaces.
